(19) United States
(12) Patent Application Publication
(10) Pub. No.: US 2025/0120080 A1
(43) Pub. Date: Apr. 10, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Junhyoung Kim, Suwon-si (KR); Bumkyu Kang, Suwon-si (KR); Sehoon Lee, Suwon-si (KR); Sukkang Sung, Suwon-si (KR)

(21) Appl. No.: 18/666,888

(22) Filed: May 17, 2024

(30) Foreign Application Priority Data
Oct. 10, 2023 (KR) 10-2023-0134338

(51) Int. Cl. H10B 43/27; H01L 25/065; H10B 41/10; H10B 41/27; H10B 41/35; H10B 43/10; H10B 43/35; H10B 80/00

(52) U.S. Cl. CPC H10B 43/27; H01L 25/0652; H10B 41/10; H10B 41/27; H10B 41/35; H10B 43/10; H10B 43/35; H10B 80/00; H01L 2225/06506

(57) ABSTRACT

A semiconductor device includes a first substrate structure, and a second substrate structure connected to the first substrate structure and including circuit elements and second bonding metal layers. The first substrate structure includes gate electrodes stacked along a first direction, a supporter layer on the gate electrodes, channel structures extending along the first direction while penetrating the gate electrodes, separation regions extending in the first direction and a second direction by penetrating through the gate electrodes, and first bonding metal layers connected to the second bonding metal layers. The separation regions respectively include first regions spaced apart from each other along the second direction and a second region surrounding side surfaces of the first regions and extending in the second direction. The first regions and the channel structures penetrate the supporter layer, and a portion of a lower surface of the supporter layer is in contact with the second region.

### CROSS-REFERENCE TO RELATED APPLICATION(S)

This application claims the benefit under 35 USC 119(a) of Korean Patent Application No. 10-2023-0134338 filed on Oct. 10, 2023, in the Korean Intellectual Property Office, the entire disclosure of which is incorporated herein by reference for all purposes.

### FIELD

The present inventive concept relates to semiconductor devices and data storage systems including the same.

### BACKGROUND

In data storage systems requiring data storage, semiconductor devices capable of storing high-capacity data may be required. Accordingly, methods to increase a data storage capacity of semiconductor devices are being researched. For example, as one method for increasing a data storage capacity of a semiconductor device, a semiconductor device including memory cells arranged three-dimensionally instead of memory cells arranged two-dimensionally has been proposed.

### SUMMARY

Example embodiments provide a semiconductor device having improved reliability and integration.

Example embodiments provide a data storage system including a semiconductor device with improved reliability and integration.

According to example embodiments, a semiconductor device includes a first substrate structure, and a second substrate structure connected to the first substrate structure and including a substrate, circuit elements on a lower surface of the substrate that faces the first substrate structure, and second bonding metal layers between the lower surface of the substrate and the first substrate structure. The first substrate structure includes gate electrodes stacked and spaced apart from each other along a first direction that is, perpendicular to the lower surface of the substrate, a supporter layer on the gate electrodes, channel structures extending in the first direction and penetrating the gate electrodes, and respectively including a channel layer and a channel pad on a lower end, separation regions extending in the first direction and in a second direction that is perpendicular to the first direction, the separation regions penetrating the gate electrodes and being spaced apart from each other along a third direction that is perpendicular to the first and second directions, and first bonding metal layers connected to the second bonding metal layers. The separation regions respectively include first regions spaced apart from each other along the second direction and a second region on side surfaces of the first regions and extending in the second direction. The first regions and the channel structures penetrate the supporter layer, and a portion of a lower surface of the supporter layer is in contact with the second region.

According to example embodiments, a semiconductor device includes a first substrate structure, and a second substrate structure connected to the first substrate structure and including a substrate, circuit elements on one surface of the substrate, and second bonding metal layers on the circuit elements. The first substrate structure includes gate electrodes stacked and spaced apart from each other along a first direction that is perpendicular to the one surface of the substrate, a supporter layer on the gate electrodes, channel structures penetrating the gate electrodes, extending in the first direction, and respectively including a channel layer, separation regions extending in the first direction and in a second direction that is perpendicular to the first direction, the separation regions penetrating the gate electrodes and being spaced apart from each other along a third direction that is perpendicular to the first and second directions, and first bonding metal layers connected to the second bonding metal layers. The channel structures respectively penetrate at least a portion of the supporter layer along the first direction, and the supporter layer includes regions overlapping the respective separation regions along the first direction.

According to example embodiments, a data storage system includes a semiconductor storage device including a first substrate structure including channel structures and first bonding metal layers, a second substrate structure including circuit elements and second bonding metal layers connected to the first bonding metal layers along a bonding surface, and an input/output pad electrically connected to the circuit elements, and a controller configured to be electrically connected to the semiconductor storage device through the input/output pad, and configured to control the semiconductor storage device. The first substrate structure further includes gate electrodes stacked and spaced apart from each other along a first direction that is perpendicular to the bonding surface, a supporter layer on the gate electrodes, channel structures penetrating the gate electrodes, extending in the first direction, and respectively including a channel layer, a channel dielectric layer, and a channel pad at end portions thereof, and separation regions extending in the first direction and a second direction that is perpendicular to the first direction, the separation regions penetrating the gate electrodes. The channel structures penetrate the supporter layer, and the supporter layer is spaced apart from the channel layer by the channel dielectric layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a semiconductor device according to example embodiments;

FIGS. 2A and 2B are schematic cross-sectional views of semiconductor devices according to example embodiments;

FIG. 3 is a partially enlarged view of a semiconductor device according to example embodiments;

FIG. 4 is an exploded perspective view of a portion of a semiconductor device according to example embodiments;

FIGS. 5A and 5B are partially enlarged views illustrating semiconductor devices according to example embodiments;

FIGS. 6A and 6B are cross-sectional views and partially enlarged views illustrating semiconductor devices according to example embodiments;

FIG. 7 is a partially enlarged view illustrating a semiconductor device according to example embodiments;

FIGS. 8A and 8B are cross-sectional views and partially enlarged views illustrating semiconductor devices according to example embodiments;

FIG. 9 is a cross-sectional view illustrating a semiconductor device according to example embodiments;

FIGS. 10A, 10B, 10C, 10D, 10E, 10F, 10G, 10H, 10I, and 10J are schematic cross-sectional views illustrating a method of manufacturing a semiconductor device according to example embodiments;

FIG. 11 is a diagram schematically illustrating a data storage system including a semiconductor device according to example embodiments;

FIG. 12 is a perspective view schematically illustrating a data storage system including a semiconductor device according to an example embodiment; and

FIG. 13 is a cross-sectional view schematically illustrating a semiconductor package according to an example embodiment.

### DETAILED DESCRIPTION OF EMBODIMENTS

Hereinafter, example embodiments will be described with reference to the accompanying drawings. Below, terms such as ‘on’, ‘upper portion’, ‘upper surface’, ‘below’, ‘lower portion’, ‘lower surface’, ‘bottom’, ‘side surface’, ‘side’, and the like may be understood as referring to the drawing, unless otherwise stated. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

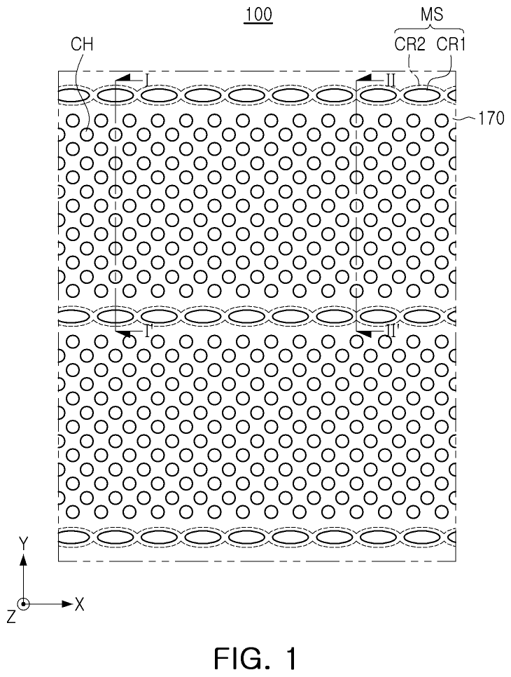

FIG. 1 is a schematic plan view of a semiconductor device according to example embodiments.

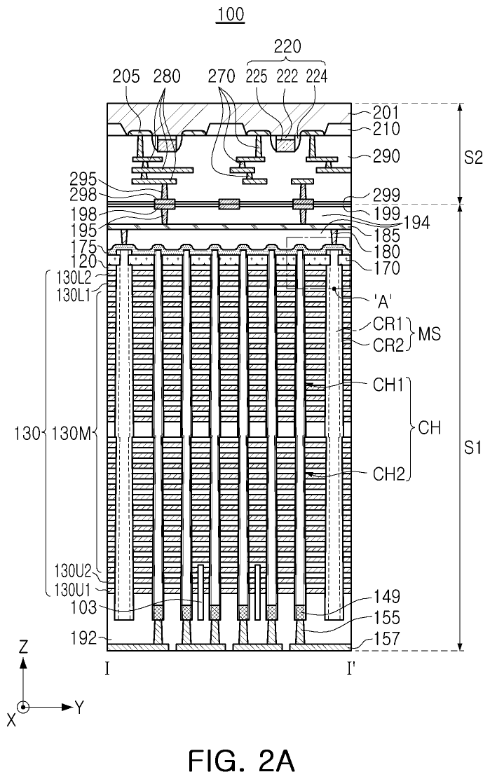

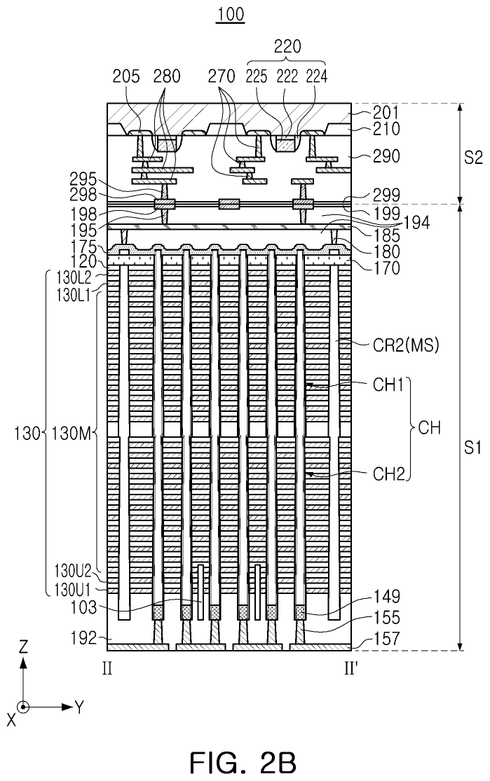

FIGS. 2A and 2B are schematic cross-sectional views of semiconductor devices according to example embodiments. FIG. 2A illustrates a cross-section along line I-I′ in FIG. 1, and FIG. 2B illustrates a cross-section along line II-II′ in FIG. 1.

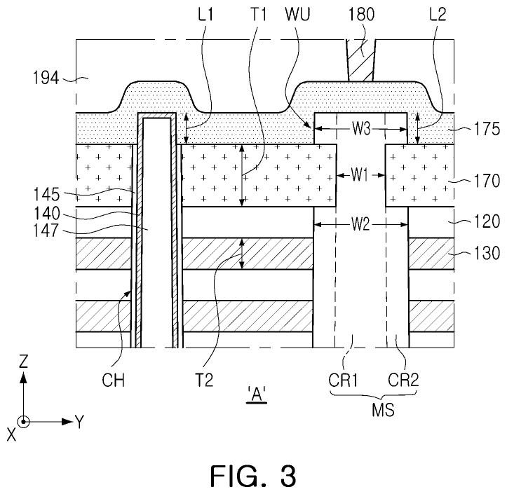

FIG. 3 is a partially enlarged view of a semiconductor device according to example embodiments. FIG. 3 illustrates an enlarged view of area ‘A’ in FIG. 2A.

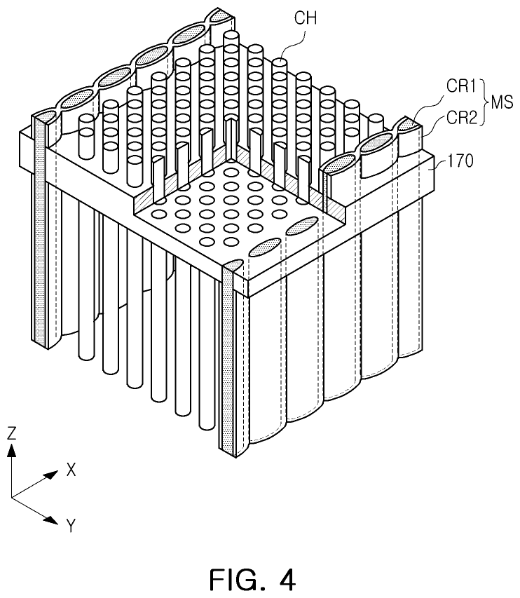

FIG. 4 is an exploded perspective view of a portion of a semiconductor device according to example embodiments.

Referring to FIGS. 1 to 4, a semiconductor device 100 may include first and second substrate structures S1 and S2 stacked vertically. For example, the first substrate structure S1 may include a memory cell region of the semiconductor device 100, and the second substrate structure S2 may include a peripheral circuit area of the semiconductor device 100. FIG. 1 illustrates a top view at the level of the upper surface of the supporter layer 170, and FIGS. 1 and 4 illustrate only the supporter layer 170, channel structures CH, and separation regions MS.

The first substrate structure S1 may include vertically stacked gate electrodes 130, gate electrodes 130 and interlayer insulating layers 120 alternately stacked, a supporter layer 170 disposed on the gate electrodes 130, channel structures CH disposed to penetrate the gate electrodes 130 and the supporter layer 170, separation regions MS extending in one direction through the gate electrodes 130, and source conductive layer 175 on supporter layer 170. The first substrate structure S1 may further include lower insulating layers 103 penetrating a portion of the gate electrodes 130, first and second cell region insulating layers 192 and 194, source contacts 180 connected to the source conductive layer 175, a cell interconnection line 185 on source contacts 180, cell contact plugs 155 disposed below the gate electrodes 130 and the channel structures CH, and cell interconnection lines 157. The first substrate structure S1 may further include first bonding vias 195, first bonding metal layers 198, and first bonding insulating layer 199 as a first bonding structure.

The gate electrodes 130 may be stacked vertically spaced apart on the lower surface of the supporter layer 170 to form a stack structure together with the interlayer insulating layers 120. The stack structure may include vertically stacked lower and upper stack structures. However, depending on embodiments, the laminated structure may be composed of a single laminated structure.

The gate electrodes 130 may include a first upper gate electrode 130U1 forming string selection transistors, a second upper gate electrode 130U2 forming an erase transistor, memory gate electrodes 130M forming a plurality of memory cells, a first lower gate electrode 130L1 constituting an erase transistor, and a second lower gate electrode 130L2 constituting the ground selection transistor. In this case, the first and second lower gate electrodes 130L1 and 130L2 and the first and second upper gate electrodes 130U1 and 130U2 may be referred to as “lower” and “upper” based on the direction during the manufacturing process. Spatially relative terms such as “above,” “upper,” ‘below,” “lower,” “under,” “over,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The number of memory gate electrodes 130M forming memory cells may be determined depending on the capacity of the semiconductor device 100. Depending on the example embodiment, the number of first and second upper gate electrodes 130U1 and 130U2 may be one to four or more, respectively, and may have the same or different structure as the memory gate electrodes 130M. In some embodiments, the positions of the first lower gate electrode 130L1 and the second lower gate electrode 130L2 may be exchanged. In some embodiments, the second upper gate electrode 130U2 and/or the first lower gate electrode 130L1 may be omitted. In some embodiments, some of the memory gate electrodes 130M may be dummy gate electrodes.

The gate electrodes 130 may be disposed to be at least partially separated by separation regions MS along the Y-direction. The gate electrodes 130 between a pair of adjacent separation regions MS may form one memory block. The range of the memory block is not limited thereto.

Interlayer insulating layers 120 may be disposed between the gate electrodes 130. Like the gate electrodes 130, the interlayer insulating layers 120 may be disposed to be spaced apart from each other in a direction perpendicular to the lower surface of the supporter layer 170 and extend along the X and Y-directions. The interlayer insulating layers 120 may include an insulating material such as silicon oxide or silicon nitride.

The channel structures CH penetrate the gate electrodes 130 and the supporter layer 170, and may be disposed to be spaced apart from each other, forming rows and columns in a plan view. The channel structures CH may be disposed to form a grid pattern or may be disposed in a zigzag shape in one direction. The channel structures CH have a pillar shape, and depending on the aspect ratio, the side surface may be inclined so that the width decreases as it approaches the supporter layer 170 or the source conductive layer 175. Each of the channel structures CH may have a shape in which first and second channel structures CH1 and CH2 penetrating the upper and lower stack structures of the gate electrodes 130, respectively, are connected to each other, and may have a bending portion due to differences or changes in width in the connection region. The upper ends of the channel structures CH may be located at a higher level than the upper surface of the supporter layer 170.

Each of the channel structures CH may include a channel layer 140, a channel dielectric layer 145, a buried channel insulating layer 147, and a channel pad 149 disposed in a channel hole, as illustrated in FIG. 3. The channel layer 140 may be formed in an annular shape surrounding the internal buried channel insulating layer 147, and depending on the example embodiment, may have a pillar shape such as a cylinder or a prism without the buried channel insulating layer 147. The channel layer 140 may include a semiconductor material such as polycrystalline silicon or single crystalline silicon. In some embodiments, the channel layer 140 may further include impurities due to doping, for example, n-type impurities, in at least some regions.

As illustrated in FIG. 3, at the upper end of the channel structure CH, the upper end of the channel layer 140 may be exposed from the channel dielectric layer 145. The term “exposed,” may be used to describe relationships between elements and/or certain intermediate processes in fabricating a completed semiconductor device, but may not necessarily require exposure of the particular region, layer, structure or other element in the context of the completed device. The upper end of the channel layer 140 may refer to an area protruding upward or away from the supporter layer 170. The upper end of the channel layer 140 may be in direct contact with the source conductive layer 175 and may be surrounded by the source conductive layer 175. By this arrangement, the channel layer 140 may be physically and electrically connected to the source conductive layer 175. The term “surround” or “cover” or “fill” as may be used herein may not require completely surrounding or covering or filling the described elements or layers, but may, for example, refer to partially surrounding or covering or filling the described elements or layers, for example, with voids or other spaces throughout. The length L1 or height of the upper end of the channel layer 140, which may refer to the distance of protrusion of the channel layer 140 beyond the supporter layer 170 (e.g., in a direction towards the source conductive layer 175), may vary in various embodiments. More generally, the term “height” may be used herein to refer to a distance from a reference surface.

The channel dielectric layer 145 may be disposed between the gate electrodes 130 and the channel layer 140. The channel dielectric layer 145 may extend vertically along channel layer 140. In some embodiments, the channel dielectric layer 145 extends horizontally along the upper and lower surfaces of the gate electrodes 130, and may further include a layer covering a side surface of the gate electrodes 130 facing the channel structure CH. Although not specifically illustrated, the channel dielectric layer 145 may include a tunneling layer, a charge storage layer, and a blocking layer sequentially stacked from the channel layer 140. The tunneling layer may tunnel charges into the charge storage layer, and for example, may include silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), high-k dielectric material, or combinations thereof.

The channel pad 149 may be disposed only at the bottom of the lower second channel structure CH2. The channel pad 149 may be located at an end of the channel structure CH farthest from the bonding surfaces of the first and second substrate structures S1 and S2. The channel pad 149 may include, for example, a doped semiconductor layer. For example, the channel pad 149 may be formed of polycrystalline silicon containing n-type impurities.

The channel layer 140, the gate dielectric layer 145, and the buried channel insulating layer 147 may be connected to each other between the first channel structure CH1 and the second channel structure CH2. An interlayer insulating layer 120 with a relatively thick thickness may be further disposed between the first channel structure CH1 and the second channel structure CH2. However, the shape of the interlayer insulating layers 120 may vary in various embodiments.

The separation regions MS may be disposed to extend along the X-direction through the gate electrodes 130. The separation regions MS may be disposed parallel to each other. In this embodiment, the separation regions MS may penetrate the entirety of the stacked gate electrodes 130. A portion of each of the separation regions MS may penetrate the supporter layer 170, and the other portion may not penetrate the supporter layer 170. In this embodiment, the upper ends of the separation regions MS may be located at a higher level than the upper surface of the supporter layer 170.

Each of the separation regions MS may include a plurality of first regions CR1 and one second region CR2 extending to surround the side surfaces of the first regions CR1. The first regions CR1 may completely penetrate the supporter layer 170. The second region CR2 does not penetrate the supporter layer 170 and may be located below the supporter layer 170. The second region CR2 may be located along the perimeter of the first regions CR1 on the supporter layer 170. The upper surface of the second region CR2 may contact the lower surface of the supporter layer 170, and the second region CR2 may overlap the supporter layer 170 in the Z-direction. Components or layers described with reference to “overlap” in a particular direction may be at least partially obstructed by one another when viewed along a line extending in the particular direction or in a plane perpendicular to the particular direction.

As illustrated in FIGS. 1 and 4, the first region CR1 may have a shape such as an elliptical shape or an elongated shape with a relatively long length along the X-direction. In some embodiments, the first region CR1 may have a circular shape. The second region CR2 has a shape enlarged from the plurality of first regions CR1, and may have a form of connecting the plurality of first regions CR1 to each other in the X-direction, at least below the supporter layer 170. Accordingly, in a plan view, the second region CR2 may have a curved side surface corresponding to the plurality of first regions CR1. In example embodiments, the relative sizes, such as widths, of the first region CR1 and the second region CR2 may vary.

As illustrated in FIG. 3, in the separation region MS, the first width W1 in the area penetrating the supporter layer 170 may be smaller than the second width W2 below the supporter layer 170. Accordingly, the separation region MS may have a bent or stepped portion (e.g., a portion having a step difference) along the lower surface of the supporter layer 170. In the separation region MS, the region on the supporter layer 170 may be referred to as the upper region WU. The third width W3 of the upper region WU is illustrated to be larger than the first width W1 of the first region CR1 penetrating the supporter layer 170, but the present inventive concept is not limited thereto. In some embodiments, the third width W3 may be equal to or smaller than the first width W1. The height L2 of the upper region WU (i.e., the distance of protrusion of the separation region MS beyond the supporter layer 170) may be equal to or greater than the protrusion length L1 of the channel layer 140, and may be modified variously in example embodiments. In some embodiments, the separation region MS may not include the upper region WU. In this case, the upper surface of the separation regions MS may be coplanar with the upper surface of the supporter layer 170.

The separation regions MS may have inclined side surfaces so that the width decreases toward the supporter layer 170 due to the high aspect ratio. The separation regions MS may comprise an insulating material, and for example, may include silicon oxide, silicon nitride, or silicon oxynitride.

The supporter layer 170 may be disposed between the gate electrodes 130 and the source conductive layer 175. The supporter layer 170 may be disposed between the gate electrodes 130 and the bonding surfaces of the first and second substrate structures S1 and S2. The supporter layer 170 may be penetrated by the upper ends of the channel structures CH, and the supporter layer 170 may be penetrated by the first regions CR1 of the separation regions MS. The supporter layer 170 may be used as an etch stop layer when forming channel holes in which the channel structures CH are disposed. The supporter layer 170 may be formed of a material having etch selectivity with respect to or is otherwise different than a material of the interlayer insulating layers 120. The supporter layer 170 may support the stack structure of the interlayer insulating layers 120 when forming the gate electrodes 130.

The supporter layer 170 may include a region that is penetrated by each of the separation regions MS and a region that is not penetrated. The supporter layer 170 may be penetrated by the first regions CR1 of the separation region MS, and may not penetrate through the second region CR2. Accordingly, the supporter layer 170 may include regions crossing the separation regions MS in a direction perpendicular to the direction in which the separation regions MS extend, for example, in the Y-direction, on the separation regions MS, as illustrated in FIG. 1. The supporter layer 170 may include areas connected in the form of a bridge between adjacent memory blocks. The supporter layer 170 may include regions that overlap with the separation regions MS in the Z-direction. For example, the supporter layer 170 may overlap the second region CR2 in the Z-direction. The supporter layer 170 may include regions that do not overlap with the separation regions MS in the Z-direction. For example, the supporter layer 170 may not overlap the first regions CR1 in the Z-direction. The supporter layer 170 surrounds the first regions CR1 and contacts the first regions CR1 through inner side surfaces, and may be in contact with the second region CR2 through at least a portion of the lower surface.

The supporter layer 170 may be spaced apart from the channel layers 140 of the channel structures CH by channel dielectric layers 145. The supporter layer 170 may include an insulating material or a conductive material. When the supporter layer 170 includes a conductive material, the supporter layer 170 may function as a common source line together with the source conductive layer 175, and may be electrically connected to the channel layer 140. The supporter layer 170 may include a material that is not etched by hydrofluoric acid (HF) and/or phosphoric acid (H₃PO₄), and may include a material different from the interlayer insulating layers 120. For example, the supporter layer 170 may include at least one of Si, SiGe, SiC, and AlₓO_{y}, or may include a metal material. A thickness T1 of the supporter layer 170 may be greater than a thickness T2 of the gate electrode 130, but is not limited thereto.

The source conductive layer 175 may be disposed on the supporter layer 170, and may be electrically connected by directly contacting the channel layers 140 of the channel structures CH. The source conductive layer 175 may function as a common source line. The source conductive layer 175 may have a larger area on a plane than the supporter layer 170. For example, the source conductive layer 175 may be located on regions where the supporter layer 170 is not disposed through the first regions CR1. The source conductive layer 175 may overlap the entire separation region MS, including the second region CR2, in the Z-direction. The source conductive layer 175 may include a conductive material, for example, polycrystalline silicon. In some embodiments, the source conductive layer 175 may include the same material as the supporter layer 170.

The source contacts 180 may be disposed on the source conductive layer 175 and connected to the source conductive layer 175. The source contacts 180 may have a line or via shape. The source contacts 180 may be disposed on upper end of the separation regions MS, but are not limited thereto. The upper interconnection line 185 may be disposed on the source contacts 180 and connected to the source contacts 180. The upper interconnection line 185 may transmit an electrical signal to the source conductive layer 175 through the source contacts 180. Separate interconnection lines constituting the cell interconnection structure may be further disposed on the upper interconnection line 185.

The source contacts 180 and the upper interconnection line 185 may include a metallic material, and for example, may include aluminum (Al), copper (Cu), tungsten (W), titanium (Ti), tungsten nitride (WN), tantalum nitride (TaN), titanium nitride (TiN), or combinations thereof.

The lower insulating layers 103 may extend along the X-direction between the separation regions MS. The lower insulating layers 103 may be disposed to penetrate a portion of the gate electrodes 130 including a lowermost first upper gate electrode 130U1 among the gate electrodes 130. For example, the lower insulating layers 103 may separate a total of three gate electrodes 130, including the first upper gate electrode 130U1, from each other in the Y-direction. However, the number of gate electrodes 130 separated by the lower insulating layers 103 may vary in various embodiments. The first upper gate electrodes 130U1 separated by the lower insulating layers 103 may form different string selection lines. The lower insulating layers 103 may include an insulating material, for example, silicon oxide, silicon nitride, or silicon oxynitride.

The cell contact plugs 155 may be connected to channel pads 149. The cell contact plugs 155 may have a cylindrical shape. The cell contact plugs 155 may have side surfaces inclined so that their width decreases toward the supporter layer 170 or the second substrate structure S2. The cell interconnection lines 157 may have a linear or line shape extending along at least one direction. The cell interconnection lines 157 may be electrically connected to the channel structures CH and may correspond to or be electrically connected to the bit line.

Cell contact plugs 155 and cell interconnection lines 157 may include, for example, tungsten (W), aluminum (Al), copper (Cu), tungsten nitride (WN), tantalum nitride (TaN), titanium nitride (TiN), or combinations thereof.

The first cell region insulating layer 192 may be disposed below the gate electrodes 130. The second cell region insulating layer 194 may be disposed on the source conductive layer 175. The first and second cell region insulating layers 192 and 194 may be formed of an insulating material and may each be formed of a plurality of insulating layers.

The first bonding vias 195 of the first bonding structure may be disposed on the upper interconnection line 185, and the first bonding metal layers 198 of the first bonding structure may be connected to first bonding vias 195. The upper surface of the first bonding metal layers 198 may be exposed to the upper surface of the first substrate structure Si. The first bonding metal layers 198 may be connected to the second bonding metal layers 298 of the second substrate structure S2 by bonding. The first bonding vias 195 and the first bonding metal layers 198 may include a conductive material, for example, copper (Cu). The first bonding insulating layer 199 may form dielectric-dielectric bonding with the second bonding insulating layer 299 of the second substrate structure S2. The first bonding insulating layer 199 may include, for example, at least one of SiO, SiN, SiCN, SiOC, SiON, and SiOCN.

The second substrate structure S2 may include a substrate 201, source/drain regions 205 and device isolation layers 210 within the substrate 201, circuit elements 220 disposed on the lower surface of the substrate 201, circuit contact plugs 270, circuit interconnection lines 280, a peripheral area insulating layer 290, second bonding vias 295, second bonding metal layers 298, and a second bonding insulating layer 299.

The substrate 201 may have a lower surface extending along the X and Y-directions. Device isolation layers 210 may be formed on the substrate 201 to define an active region. Source/drain regions 205 containing impurities may be disposed in a portion of the active region. The substrate 201 may include a semiconductor material, such as a group IV semiconductor, a group III-V compound semiconductor, or a group II-VI compound semiconductor. For example, the substrate 201 may be provided as a single crystal bulk wafer.

The circuit elements 220 may include planar transistors. Each circuit element 220 may include a circuit gate dielectric layer 222, spacer layers 224, and a circuit gate electrode 225. Source/drain regions 205 may be disposed within the substrate 201 on both side surfaces of the circuit gate electrode 225.

The peripheral area insulating layer 290 may be disposed to cover the circuit element 220. The circuit contact plugs 270 and circuit interconnection lines 280 may form a second interconnection structure of the second substrate structure S2. The circuit contact plugs 270 have a cylindrical shape, and may be connected to the source/drain regions 205 through the peripheral region insulating layer 290. An electrical signal may be applied to the circuit element 220 through the circuit contact plugs 270. In an area not illustrated, circuit contact plugs 270 may also be connected to the circuit gate electrode 225. The circuit interconnection lines 280 may be connected to circuit contact plugs 270, may have a linear or line shape, and may be disposed in multiple layers. In example embodiments, the number of layers of circuit contact plugs 270 and circuit interconnection lines 280 may vary.

The second bonding vias 295, the second bonding metal layers 298, and the second bonding insulating layer 299 constitute a second bonding structure, and may be disposed under a portion of the lowest circuit interconnection lines 280. The second bonding vias 295 have a cylindrical shape, and the second bonding metal layers 298 may have a circular pad shape in a plan view or a relatively short linear or line shape. Lower surfaces of the second bonding metal layers 298 may be exposed to the lower surface of the second substrate structure S2. The second bonding vias 295 and the second bonding metal layers 298 may function as a bonding structure or bonding layer of or between the first substrate structure S1 and the second substrate structure S2. Additionally, the second bonding vias 295 and the second bonding metal layers 298 may provide an electrical connection path with the first substrate structure S1. In example embodiments, some of the second bonding metal layers 298 may not be connected to the underlying circuit interconnection lines 280 and may be disposed only for bonding, as illustrated in FIGS. 2A and 2B. The second bonding vias 295 and the second bonding metal layers 298 may include a conductive material, for example, copper (Cu).

The second bonding insulating layer 299 may be disposed with a predetermined thickness from the lower surface of the peripheral area insulating layer 290. The second bonding insulating layer 299 may be a layer for dielectric-to-dielectric bonding with the first bonding insulating layer 199 of the first substrate structure S1. The second bonding insulating layer 299 may also function as a diffusion prevention layer of the second bonding metal layers 298 and may include, for example, at least one of SiO, SiN, SiCN, SiOC, SiON, and SiOCN.

The first and second substrate structures S1 and S2 may be bonded by bonding the first bonding metal layers 198 and the second bonding metal layers 298 and bonding the first bonding insulating layer 199 and the second bonding insulating layer 299. The bonding of the first bonding metal layers 198 and the second bonding metal layers 298 may be, for example, copper (Cu)-to-copper (Cu) bonding, and the bonding of the first bonding insulating layer 199 and the second bonding insulating layer 299 may be, for example, dielectric-to-dielectric bonding such as SiCN-to-SiCN bonding. The first and second substrate structures S1 and S2 may be bonded by hybrid bonding including copper (Cu)-to-copper (Cu) bonding and dielectric-to-dielectric bonding.

The first and second substrate structures S1 and S2 may be packaged in a form in which the first substrate structure S1 is located below, as illustrated in FIGS. 2A and 2B. Alternatively, the first and second substrate structures S1 and S2 may be packaged upside down with the second substrate structure S2 located below.

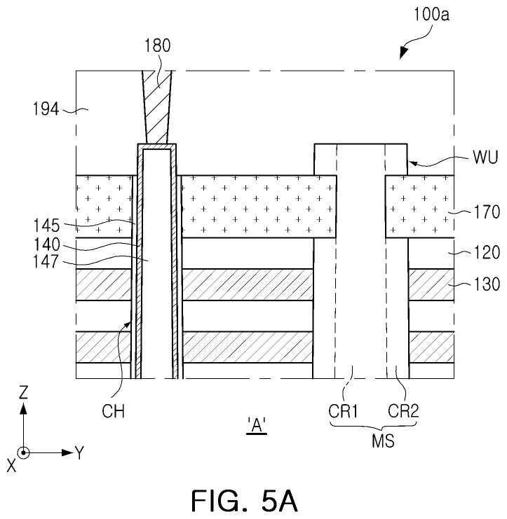

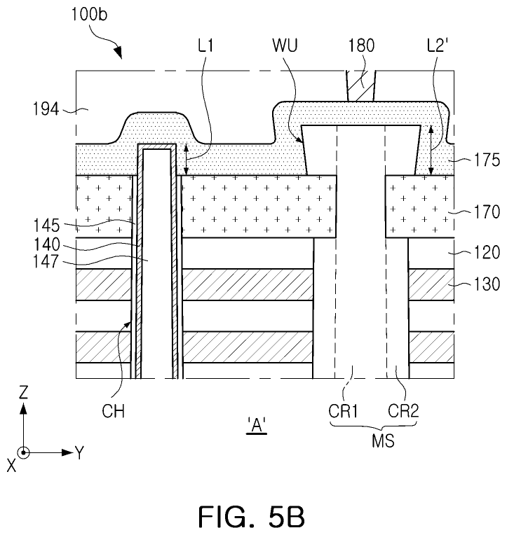

FIGS. 5A and 5B are partially enlarged views illustrating semiconductor devices according to example embodiments. FIGS. 5A and 5B each illustrate areas corresponding to FIG. 3.

Referring to FIG. 5A, in a semiconductor device 100a, the first substrate structure S1 may not include the source conductive layer 175 (see FIGS. 2A to 3), and the arrangement position of the source contact 180 may be different from that in the example embodiments of FIGS. 2A to 3. In this embodiment, the source contact 180 may be directly connected to the channel layer 140 of the channel structure CH. Accordingly, the source contact 180 may be connected to each channel structure CH.

Referring to FIG. 5B, in a semiconductor device 100b, the shape of the upper region WU of the separation region MS may be different from that in the example embodiments of FIGS. 2A to 3. The upper region WU may have a height L2′ greater than the protrusion length L1 of the channel layer 140, and may have an inclined side surface so that the width decreases toward the supporter layer 170. In example embodiments, the width of the upper area WU may be varied.

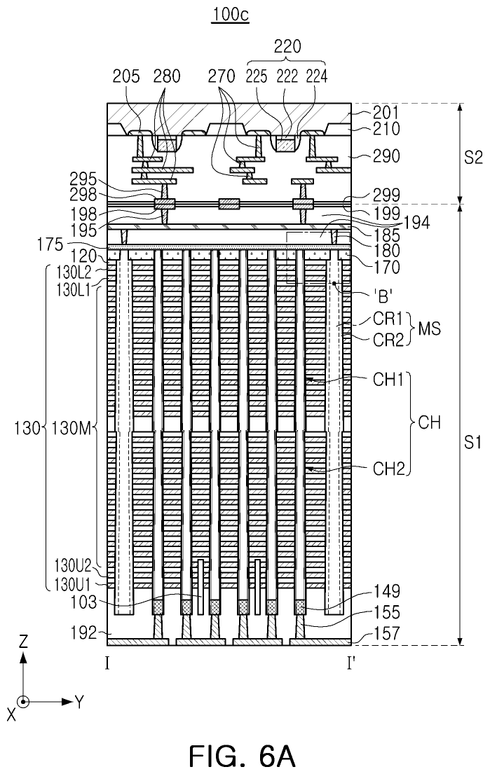

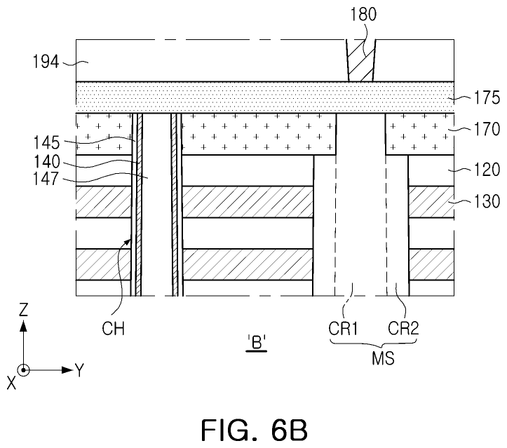

FIGS. 6A and 6B are cross-sectional views and partially enlarged views illustrating semiconductor devices according to example embodiments. FIG. 6A illustrates the area corresponding to FIG. 2A, and FIG. 6B illustrates an enlarged view of the ‘B’ area of FIG. 6A.

Referring to FIGS. 6A and 6B, in a semiconductor device 100c, the separation regions MS may not include the upper region WU (see FIG. 3), and the channel structures CH may not protrude into the source conductive layer 175.

The uppermost surface of the separation regions MS may be in contact with the lower surface of the source conductive layer 175 and may be coplanar with the upper surface of the supporter layer 170. In each of the separation regions MS, the upper surfaces of the first regions CR1 may contact the lower surface of the source conductive layer 175, and the upper surface of the second region CR2 may contact the lower surface of the supporter layer 170.

Channel structures CH may have flat upper surfaces, and the channel layers 140 may contact the source conductive layer 175 through their upper surfaces. In some embodiments, the source conductive layer 175 may partially recess or extend into the channel dielectric layer 145 and partially extend downward along the channel layer 140.

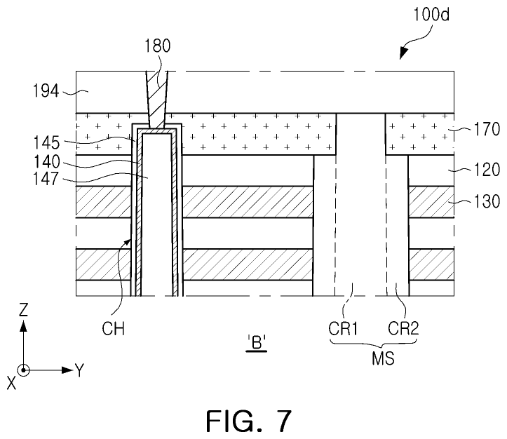

FIG. 7 is a partially enlarged view illustrating a semiconductor device according to example embodiments. FIG. 7 illustrates the area corresponding to FIG. 6B.

Referring to FIG. 7, in a semiconductor device 100d, at least some of the channel structures CH may only partially penetrate the supporter layer 170, and the first substrate structure S1 may not include the source conductive layer 175 (see 6A and 6B).

The channel structure CH may not completely penetrate (i.e., may not extend completely through) the supporter layer 170 in the Z-direction. The source contact 180 may be directly connected to the channel layer 140 of the channel structure CH. The source contact 180 may be connected to the channel layer 140 by penetrating a portion of the supporter layer 170 and the channel dielectric layer 145.

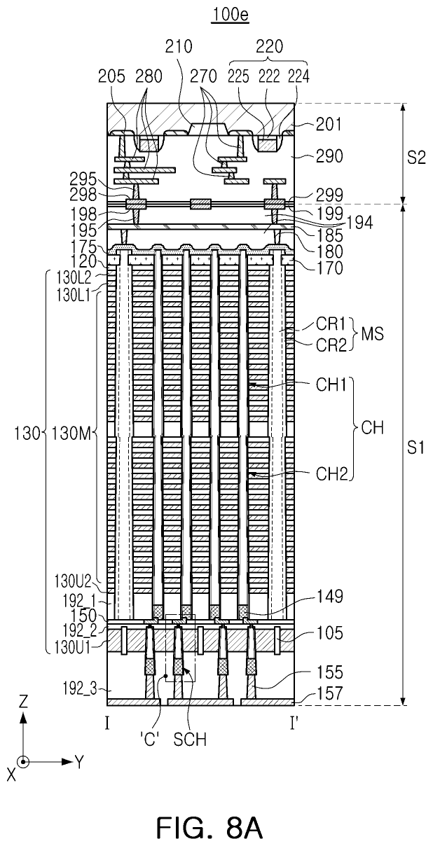

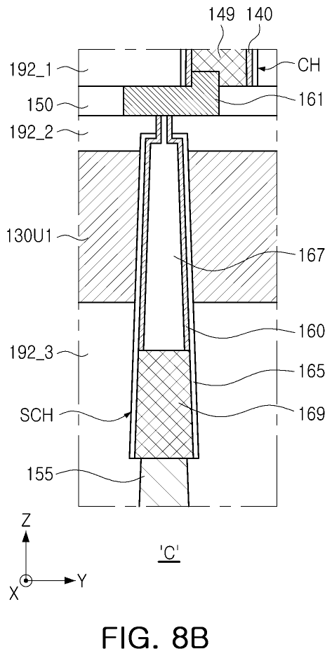

FIGS. 8A and 8B are cross-sectional views and partially enlarged views illustrating semiconductor devices according to example embodiments. FIG. 8A illustrates the area corresponding to FIG. 2A, and FIG. 8B illustrates an enlarged view of the ‘C’ area of FIG. 8A.

Referring to FIGS. 8A and 8B, in a semiconductor device 100e, the first substrate structure S1 may further include string channel structures SCH connected to the channel structures CH and a horizontal insulating layer 150. Additionally, the first cell region insulating layers 192_1, 192_2, and 192_3 may include an upper layer 192_1, a middle layer 192_2, and a lower layer 192_3.

The lowermost first upper gate electrode 130U1 among the gate electrodes 130 may be disposed to be relatively thick. The string channel structures SCH may be disposed to penetrate the first upper gate electrode 130U1, and the channel structures CH may be disposed to penetrate the gate electrodes 130 except for the first upper gate electrode 130U1.

String channel structures SCH may be respectively connected to channel structures CH. The string channel structures SCH may be respectively disposed below the channel structures CH and may be disposed shifted along the horizontal direction from the channel structures CH, but the present inventive concept is not limited thereto. As illustrated in FIG. 8B, the string channel structures SCH may each include a string channel layer 160, a connection pad 161, a string channel dielectric layer 165, a string buried channel insulating layer 167, and a string channel pad 169, that are disposed within a string channel hole.

The string channel layer 160 may be formed in an annular shape surrounding the internal string buried channel insulating layer 167. The string channel layer 160 may be connected to the connection pad 161 on the upper end, and may be electrically connected to the channel layer 140 of the channel structure CH through the connection pad 161. The connection pad 161 may be disposed on the string channel layer 160 and may be disposed in a partially recessed form of the channel pads 149. In some embodiments, the connection pad 161 and the string channel layer 160 may be formed integrally.

Regarding the description of the materials of the string channel layer 160, the string channel dielectric layer 165, the string buried channel insulating layer 167 and the string channel pad 169, the descriptions for each of the above-described channel layer 140, channel dielectric layer 145, buried channel insulating layer 147, and channel pad 149 may be equally or similarly applied. The connection pad 161 may include a conductive material, for example, polycrystalline silicon.

The horizontal insulating layer 150 may be disposed between the channel structures CH and the string channel structures SCH and extend horizontally. The horizontal insulating layer 150 may be disposed between the first upper gate electrode 130U1 and the second upper gate electrode 130U2. The horizontal insulating layer 150 may be used as an etch stop layer when forming string channel structures SCH, and may also be a layer used when forming the connection pads 161. In some embodiments, the horizontal insulating layer 150 may not be disposed below the separation regions MS. The horizontal insulating layer 150 may include an insulating material and may include a material different from the first cell region insulating layers 192_1, 192_2, and 192_3.

The shape of the string channel structures SCH and the horizontal insulating layer 150 of this embodiment may also be applied to the example embodiments of FIGS. 1 to 7.

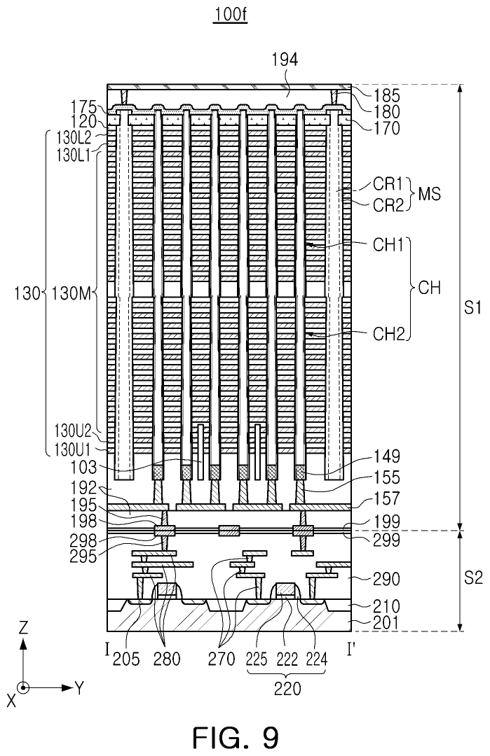

FIG. 9 is a cross-sectional view illustrating a semiconductor device according to example embodiments. FIG. 9 illustrates the area corresponding to FIG. 2A.

Referring to FIG. 9, the bonding direction of the first and second substrate structures S1 and S2 of the semiconductor device 100f may be different from that of the example embodiment of FIGS. 2A and 2B. In detail, positions in the first substrate structure S1 where the first bonding structure including the first bonding metal layers 198 are disposed may be areas adjacent to the channel pads 149. Accordingly, the supporter layer 170 may be located on the opposite side from the first and second substrate structures S1 and S2 with respect to the gate electrodes 130.

The second substrate structure S2 may be disposed with the substrate 201 disposed below and the second bonding metal layers 298 exposed through the upper surface. The first substrate structure S1 may be bonded to the second substrate structure S2 by having the first bonding structure disposed below the upper interconnection lines 157. The semiconductor device 100f is packaged in such a way that the first substrate structure S1 is positioned on top, or the semiconductor device 100f may be packaged upside down with the first substrate structure S1 located below.

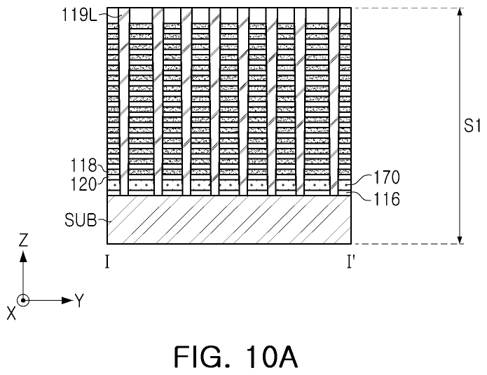

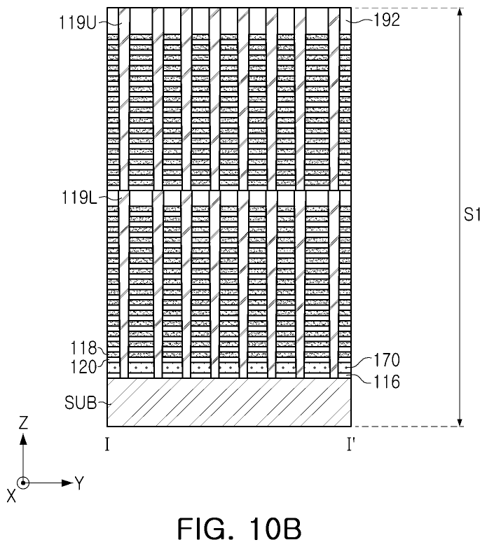

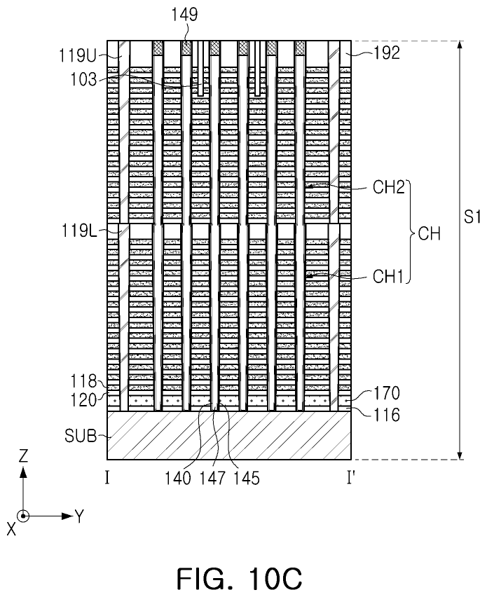

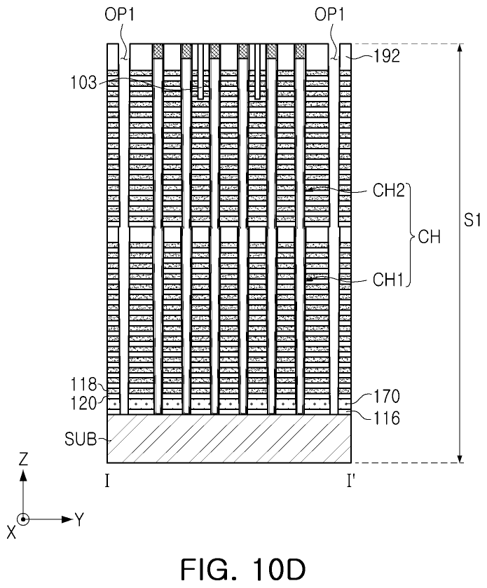

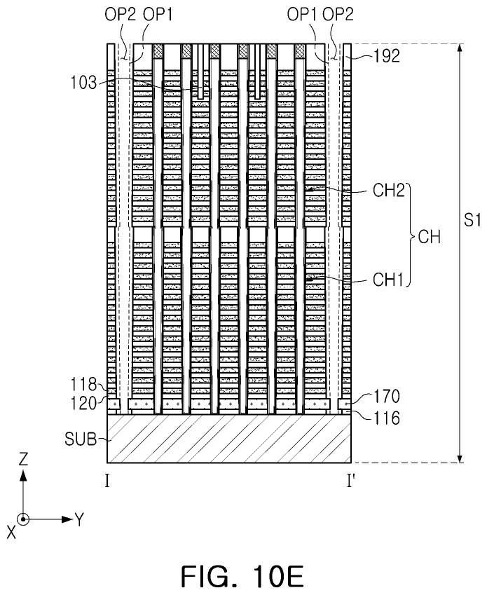

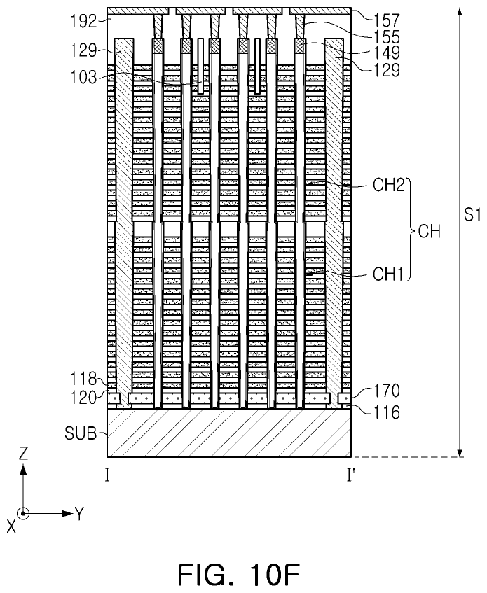

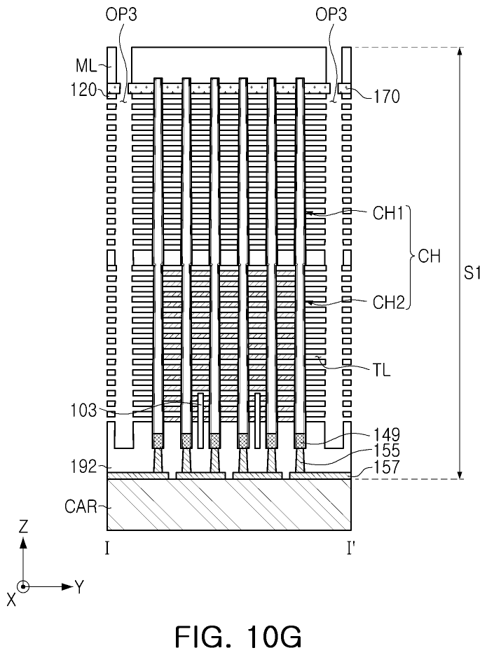

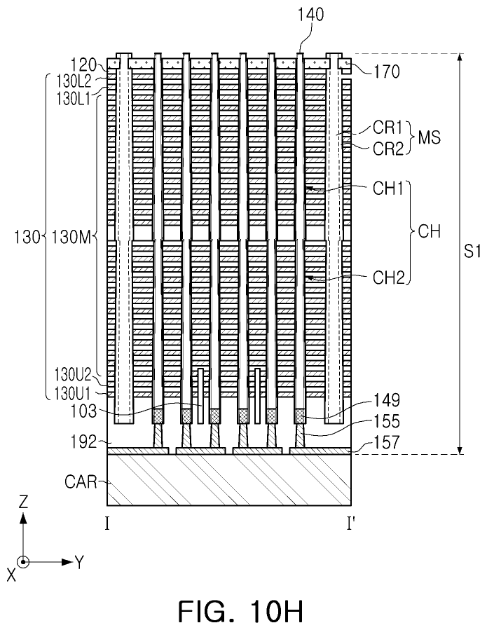

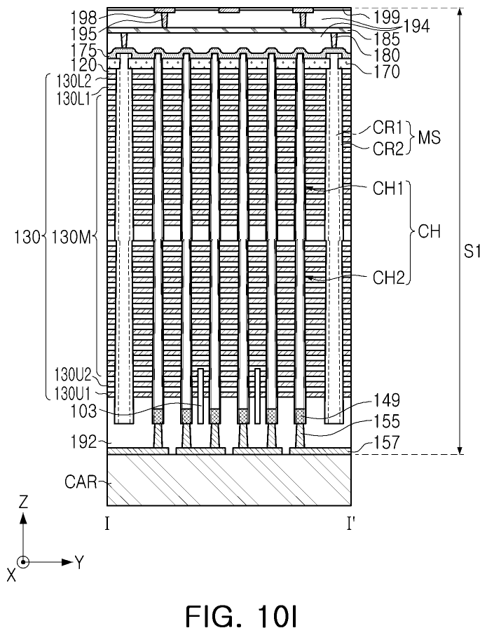

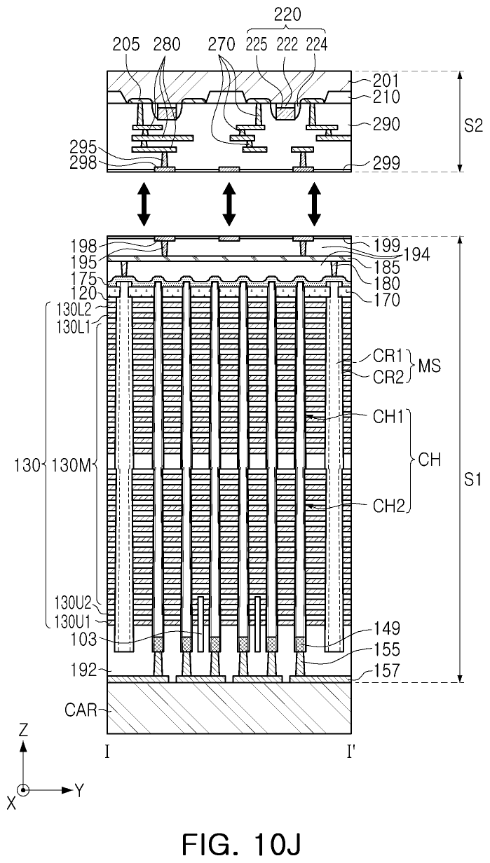

FIGS. 10A to 10J are schematic cross-sectional views for explaining a method of manufacturing a semiconductor device according to example embodiments. FIGS. 10A to 10J illustrate areas corresponding to FIG. 2A.

Referring to FIG. 10A, the manufacturing process of the first substrate structure S1 may begin. After forming the substrate insulating layer 116 and the supporter layer 170 on the base substrate SUB, sacrificial insulating layers 118 and interlayer insulating layers 120 are alternately stacked to form a lower mold structure, and lower vertical sacrificial layers 119L may be formed.

The base substrate SUB may be a layer that is removed through a subsequent process and may be a semiconductor substrate such as a silicon (Si) wafer. The substrate insulating layer 116 may be a layer that is removed through a subsequent process and may include a single layer or multiple insulating layers. The supporter layer 170 may include a material different from the substrate insulating layer 116, the sacrificial insulating layers 118, and the interlayer insulating layers 120.

The lower mold structure may be formed on the supporter layer 170 at a height where the first channel structures CH1 of the channel structures CH of FIG. 2A are disposed.

The sacrificial insulating layers 118 may be replaced as part of the fabrication of the gate electrodes 130 (see FIG. 2A) through a subsequent process. The sacrificial insulating layers 118 may be formed of a material different from the interlayer insulating layers 120, and the interlayer insulating layers 120 may be formed of a material that may be etched with etch selectivity under specific etching conditions. For example, the interlayer insulating layer 120 may be formed of at least one of silicon oxide and silicon nitride, and the sacrificial insulating layers 118 may be formed of a material different from the interlayer insulating layer 120 selected from silicon, silicon oxide, silicon carbide, and silicon nitride. In example embodiments, the thicknesses of the interlayer insulating layers 120 may not all be the same. The thickness of the interlayer insulating layers 120 and the sacrificial insulating layers 118 and the number of constituent films may vary from those illustrated.

The lower vertical sacrificial layers 119L may be formed at positions corresponding to the first channel structures CH1. The lower vertical sacrificial layers 119L may be further formed in regions corresponding to the first regions CR1 of the separation regions MS of FIG. 2A. The lower vertical sacrificial layers 119L may be formed by forming holes to penetrate the lower mold structure, depositing a material forming the lower vertical sacrificial layers 119L in the holes, and performing a planarization process. In this operation, the holes may be formed to at least partially penetrate the supporter layer 170. In some embodiments, the holes may partially recess or extend into the base substrate SUB, and the positions of the holes may be changed in various ways within the range of penetrating at least a portion of the supporter layer 170. When forming the holes, the supporter layer 170 may be used as an etch stop layer. The lower vertical sacrificial layers 119L may include, for example, carbon (C), but are not limited thereto.

Referring to FIG. 10B, the upper mold structure may be formed, and upper vertical sacrificial layers 119U may be formed penetrating the upper mold structure.

The upper mold structure may be formed on the lower mold structure at a height where the second channel structures CH2 (see FIG. 2A) of the channel structures CH are disposed. The upper mold structure may be formed by alternately stacking sacrificial insulating layers 118 and lower interlayer insulating layers 120 in the same manner as the lower mold structure. A first cell region insulating layer 192 may be formed on the uppermost sacrificial insulating layers 118.

The upper vertical sacrificial layers 119U may be formed on the lower vertical sacrificial layers 119L, respectively. The upper vertical sacrificial layers 119U may be respectively connected to the lower vertical sacrificial layers 119L. The upper vertical sacrificial layers 119U may include the same material as the lower vertical sacrificial layers 119L. The upper vertical sacrificial layers 119U may include, for example, carbon (C), but are not limited thereto.

Referring to FIG. 10C, lower insulating layers 103 and channel structures CH may be formed.

In the upper mold structure, lower insulating layers 103 may be formed by removing parts of the sacrificial insulating layers 118 and interlayer insulating layers 120. To form the lower insulating layers 103, a separate mask layer is used to expose the area where the lower insulating layers 103 are to be formed, and after removing a predetermined number of sacrificial insulating layers 118 and interlayer insulating layers 120 from the top, lower insulating layers 103 may be formed by depositing an insulating material.

Channel holes may be formed by removing some of the lower vertical sacrificial layers 119L and upper vertical sacrificial layers 119U. For example, when the lower vertical sacrificial layers 119L and upper vertical sacrificial layers 119U include carbon (C), the lower vertical sacrificial layers 119L and upper vertical sacrificial layers 119U may be removed by an ashing process. In the area corresponding to the location of the separation regions MS in FIG. 2A, the lower vertical sacrificial layers 119L and the upper vertical sacrificial layers 119U may remain without being removed.

Channel structures CH may be formed by sequentially depositing at least a portion of the channel dielectric layer 145, the channel layer 140, the buried channel insulating layer 147, and the channel pad 149 in each of the channel holes.

The channel dielectric layer 145 may be formed to have a uniform thickness using an atomic layer deposition (ALD) or chemical vapor deposition (CVD) process. In this operation, the channel dielectric layer 145 may be formed in whole or in part, and a portion extending vertically along the channel structures CH may be formed in this operation. The channel layer 140 may be formed on channel dielectric layer 145 within the channel holes. The channel filling insulating layer 147 is formed to fill the channel holes and may be formed of an insulating material. The channel pad 149 may be formed after partially removing the buried channel insulating layer 147. The channel pad 149 may be formed of a conductive material, for example, polycrystalline silicon.

Referring to FIG. 10D, first openings OP1 may be formed by removing the remaining lower vertical sacrificial layers 119L and upper vertical sacrificial layers 119U.

The lower vertical sacrificial layers 119L and upper vertical sacrificial layers 119U may be removed by, for example, an ashing process.

Referring to FIG. 10E, the first openings OP1 may be enlarged to form second openings OP2.

The second openings OP2 may be formed to connect adjacent first openings OP1 to each other in the X-direction by enlarging the size of the first openings OP1. The second openings OP2 may be formed, for example, by partially removing the stack structure of the interlayer insulating layers 120 and sacrificial insulating layers 118 exposed by the first openings OP1 using a wet etching process. Each of the first openings OP1 may be enlarged beyond the length by which adjacent first openings OP1 may be connected to each other.

At this stage, the supporter layer 170 may not be enlarged because it includes a material different from the sacrificial insulating layers 118 and the interlayer insulating layers 120. Accordingly, the second openings OP2 may have a step difference or bend along at least the upper surface of the supporter layer 170, due to the difference in size of the first openings OP1 in the supporter layer 170 and the second openings OP2 in the interlayer insulating layers 120. The substrate insulating layer 116 may be enlarged together with the sacrificial insulating layers 118 and the interlayer insulating layers 120, but is not limited thereto.

Referring to FIG. 10F, separation sacrificial layers 129 are formed in the second openings OP2, and cell contact plugs 155 and cell interconnection lines 157 may be formed.

The separation sacrificial layers 129 may include a material different from the supporter layer 170, the interlayer insulating layers 120, and the sacrificial insulating layers 118. For example, the separation sacrificial layers 129 may include at least one of polycrystalline silicon, a metal material, and carbon (C). In some embodiments, forming the second openings OP2 and forming the separation sacrificial layers 129 may be performed after the entire structure is turned over, as illustrated in FIG. 10G.

The cell contact plugs 155 may be formed by further forming a first cell region insulating layer 192 on the channel pads 149, then etching it, and depositing a conductive material. The cell interconnection lines 157 may be formed through a deposition and patterning process of a conductive material, or may be formed by patterning the same and depositing a conductive material, after forming a portion of the insulating layer forming the first cell region insulating layer 192. When a cell interconnection structure is further disposed on the cell interconnection lines 157, at least part of the cell interconnection structure may be formed in this operation.

Referring to FIG. 10G, in the structure manufactured up to the operation of FIG. 10F, a carrier substrate CAR may be attached onto the cell interconnection lines 157, and the base substrate SUB and substrate insulating layer 116 may be removed after turning the structure over. The separation sacrificial layers 129 may be removed to form third openings OP3, and the tunnel portions TL may be formed by removing the sacrificial insulating layers 118 through the third openings OP3.

The carrier substrate CAR is a layer that is removed through a subsequent process and may be a semiconductor substrate such as a silicon (Si) wafer. A portion of the base substrate SUB may be removed from the upper surface by a polishing process such as a grinding process, and the remaining part may be removed by an etching process such as wet etching and/or dry etching. Alternatively, the entire base substrate SUB may be removed through an etching process. The substrate insulating layer 116 may be removed after the base substrate SUB is removed.

The third openings OP3 may be formed by selectively removing the separation sacrificial layers 129. The process may be performed by covering the upper end of the channel structures CH using a mask layer ML, but is not limited thereto.

The sacrificial insulating layers 118 may be selectively removed with respect to the interlayer insulating layers 120 and the supporter layer 170 using, for example, wet etching. Accordingly, tunnel portions TL may be formed between the interlayer insulating layers 120. When the number of sacrificial insulating layers 118 increases, in this operation, leaning may occur in the structure of the interlayer insulating layers 120 after the sacrificial insulating layers 118 are removed. However, according to this embodiment, the supporter layer 170 extending continuously along the Y-direction is located on the upper end of the channel structures CH, and the structure of the interlayer insulating layers 120 may be stably supported.

In the case of the example embodiment of FIG. 9, a first bonding structure is further formed in the operation described above with reference to FIG. 10F, and in this operation, the entire structure may be manufactured by bonding onto the second substrate structure S2.

Referring to FIG. 10H, gate electrodes 130 may be formed in the area where the sacrificial insulating layers 118 have been removed, and after forming the separation regions MS, the channel layers 140 of the channel structures CH may be exposed.

The gate electrodes 130 may be formed by burying or otherwise forming a conductive material in the tunnel portions TL. The gate electrodes 130 may include metal, polycrystalline silicon, or metal silicide material. In some embodiments, before forming the gate electrodes 130, a dielectric layer may be formed first. In this case, the dielectric layer may be interpreted as forming a blocking structure together with the blocking layer of the channel dielectric layer 145 extending vertically along the channel structure CH. The dielectric layer may be formed to extend horizontally along the tunnel portions TL, and may be formed to cover the side walls of the channel structures CH exposed through the tunnel portions TL.

The separation regions MS may be formed by filling the third openings OP3 with an insulating material. In this operation, depending on the filling height of the insulating material, the height of the upper region WU (see FIG. 3) of the separation region MS may be changed, and depending on the shape of the mask layer ML in FIG. 10G, the shape of the upper area WU may be changed, such as in the example embodiment of FIG. 5B. In the case of the separation regions MS of the example embodiments of FIGS. 6A to 7, the separation regions MS may be formed by removing the insulating material on the supporter layer 170 and a portion of the supporter layer 170 by a planarization process such as chemical mechanical polishing (CMP).

The channel layers 140 may be exposed by removing the channel dielectric layers 145 (see FIG. 3), which are the outermost layers, from the protruding upper ends of the channel structures CH. Channel dielectric layers 145 may be selectively removed by wet etching and/or dry etching processes. In some embodiments, the channel layers 140 may be exposed during the base substrate SUB removal process described above with reference to FIG. 10G.

Referring to FIG. 10I, a source conductive layer 175 is formed on the supporter layer 170, and after forming the source contacts 180 and the upper interconnection line 185, the first bonding structure S1 may be formed.

The source conductive layer 175 may be formed on the supporter layer 170 to cover the exposed upper ends of the channel layers 140. The source conductive layer 175 may have curves along the channel structures CH and separation regions MS on the upper surface thereof.

The second cell region insulating layer 194 may be formed on the source conductive layer 175, the second cell region insulating layer 194 may be partially etched, and a conductive material may be deposited to form source contacts 180. The upper interconnection line 185 may be formed through a deposition and patterning process of a conductive material.

The first bonding vias 195 and first bonding metal layers 198 forming the first bonding structure may be formed by further forming the second cell region insulating layer 194 on the upper interconnection line 185 and forming the first bonding insulating layer 199, then partially removing it and depositing a conductive material. Upper surfaces of the first bonding metal layers 198 may be exposed from the second cell region insulating layer 194. The upper surface of the first bonding metal layers 198 may form a portion of the upper surface of the first substrate structure S1. By this, the first substrate structure S1 may be prepared.

Referring to FIG. 10J, the second substrate structure S2 may be formed, and the first substrate structure S1 and the second substrate structure S2 may be bonded.

A second substrate structure S2 including circuit elements 220, circuit interconnection structures, and a second bonding structure may be formed on the substrate 201.

Device isolation layers 210 may be formed within the substrate 201, and a circuit gate dielectric layer 222 and a circuit gate electrode 225 may be sequentially formed on the substrate 201. The device isolation layers 210 may be formed by, for example, a shallow trench isolation (STI) process. The circuit gate dielectric layer 222 and the circuit gate electrode 225 may be formed using ALD or CVD. The circuit gate dielectric layer 222 may be formed of silicon oxide, and the circuit gate electrode 225 may be formed of at least one of polycrystalline silicon or a metal silicide layer, but the present inventive concept is not limited thereto. A spacer layer 224 and source/drain regions 205 may be formed on both (e.g., opposing) sidewalls of the circuit gate dielectric layer 222 and the circuit gate electrode 225. Depending on embodiments, the spacer layer 224 may be composed of multiple layers. The source/drain regions 205 may be formed by performing an ion implantation process.

The circuit contact plugs 270 of the circuit interconnection structure and the second bonding vias 295 of the second bonding structure may be formed by removing a portion by etching and filling it with a conductive material, after partially forming the peripheral area insulating layer 290. The circuit interconnection lines 280 of the circuit interconnection structure and the second bonding metal layers 298 of the second bonding structure may be formed, for example, by depositing a conductive material and then patterning the same. The second bonding metal layers 298 may be formed so that their upper surfaces are exposed through the second bonding insulating layer 299. The upper surface of the second bonding metal layers 298 may form part of the upper surface of the second substrate structure S2.

The peripheral area insulating layer 290 may be composed of a plurality of insulating layers. The peripheral area insulating layer 290 may be partially formed in each operation of forming the circuit interconnection structure and the second bonding structure. By this operation, the second substrate structure S2 may be prepared.

The first substrate structure S1 and the second substrate structure S2 may be connected by bonding the first bonding metals 198 and the second bonding metal layers 298 by applying pressure. At the same time, the first bonding insulating layers 199 and the second bonding insulating layers 299 may also be bonded by pressure. The second substrate structure S2 on the first substrate structure S1 may be turned over so that the second bonding metal layers 298 face downward, and then bonding may be performed. The bonding may be performed by attaching a separate carrier substrate to one surface of the second substrate structure S2, for example, to one surface of the substrate 201.

The first substrate structure S1 and the second substrate structure S2 may be directly bonded without the intervention of an adhesive such as a separate adhesive layer. Depending on the example embodiment, before bonding, a surface treatment process such as hydrogen plasma treatment may be further performed on the upper surface of the first substrate structure S1 and the lower surface of the second substrate structure S2 to strengthen the bonding force.

Referring to FIG. 2A, the carrier substrate CAR of the first substrate structure S2 may be removed from the bonding structure of the first and second substrate structures S1 and S2. As a result, the semiconductor device 100 of FIG. 2A may be manufactured.

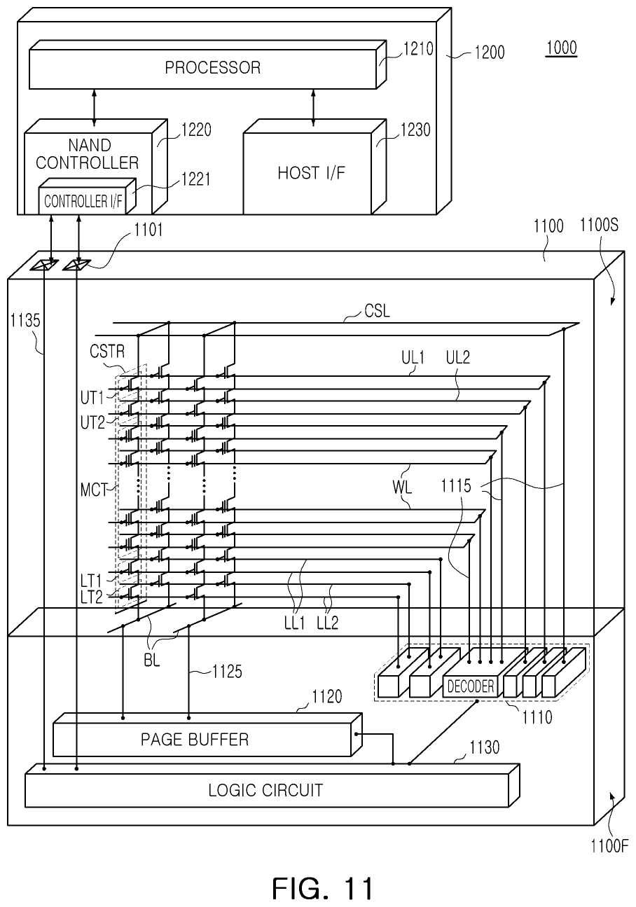

FIG. 11 is a diagram schematically illustrating a data storage system including a semiconductor device according to example embodiments.

Referring to FIG. 11, the data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD) device, a universal serial bus (USB) device, a computing system, a medical device, or a communication device including one or a plurality of semiconductor devices 1100.

The semiconductor device 1100 may be a non-volatile memory device, for example, the NAND flash memory device described above with reference to FIGS. 1 to 9. The semiconductor device 1100 may include a first structure 1100F and a second structure 1100S on the first structure 1100F. In example embodiments, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include upper transistors UT1 and UT2 adjacent to the common source line CSL, lower transistors LT1 and LT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on embodiments.

In example embodiments, upper transistors UT1 and UT2 may include string select transistors, and the lower transistors LT1 and LT2 may include a ground selection transistor. The gate lower lines LL1 and LL2 may be gate electrodes of the lower transistors LT1 and LT2, respectively. Word lines WL may be gate electrodes of memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground selection transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used in an erase operation to delete data stored in the memory cell transistors MCT using the Gate Induced Drain Leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection wires 1115 extending from the first structure 1100F to the second structure 1100S. The bit lines BL may be electrically connected to the page buffer 1120 through second connection wires 1125 extending from the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and page buffer 1120 may be controlled by the logic circuit 1130. The semiconductor device 1000 may communicate with the controller 1200 through the input/output pad 1101 that is electrically connected to the logic circuit 1130. The input/output pad 1101 may be electrically connected to the logic circuit 1130 through an input/output connection wire 1135 extending from the first structure 1100F to the second structure 1100S.

The controller 1200 may include a processor 1210, a NAND controller 1220, and a host interface 1230. Depending on embodiments, the data storage system 1000 may include a plurality of semiconductor devices 1100, and in this case, the controller 1200 may control a plurality of semiconductor devices 1100.

The processor 1210 may control the overall operation of the data storage system 1000, including the controller 1200. The processor 1210 may operate according to predetermined firmware, and the semiconductor device 1100 may be accessed by controlling the NAND controller 1220. The NAND controller 1220 may include a controller interface 1221 that processes communication with the semiconductor device 1100. Control commands for controlling the semiconductor device 1100, data to be written to the memory cell transistors MCT of the semiconductor device 1100, data to be read from the memory cell transistors MCT of the semiconductor device 1100, and the like may be transmitted through the controller interface 1221. The host interface 1230 may provide a communication function between the data storage system 1000 and an external host. When receiving a control command from an external host through the host interface 1230, the processor 1210 may control the semiconductor device 1100 in response to control commands.

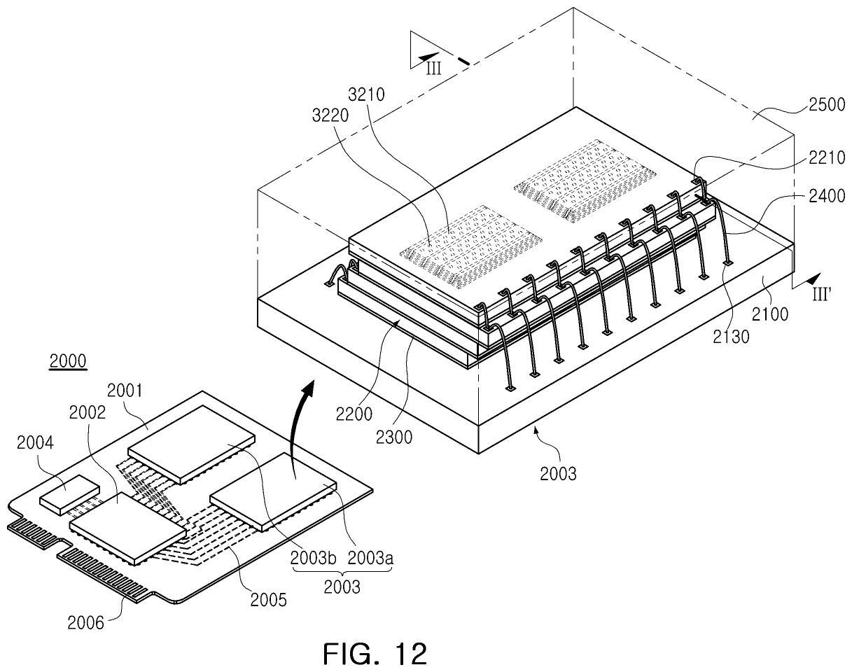

FIG. 12 is a perspective view schematically illustrating a data storage system including a semiconductor device according to an example embodiment.

Referring to FIG. 12, a data storage system 2000 according to an example embodiment of the present invention may include a main board 2001, a controller 2002 mounted on the main board 2001, one or more semiconductor packages 2003, and DRAM 2004. The semiconductor package 2003 and the DRAM 2004 may be connected to the controller 2002 through interconnection structures 2005 formed on the main substrate 2001.

The main board 2001 may include a connector 2006 including a plurality of pins that are configured to be coupled to an external host. The number and arrangement of the plurality of pins in the connector 2006 may vary depending on the communication interface between the data storage system 2000 and the external host. In example embodiments, the data storage system 2000 may communicate with an external host through any one of the following interfaces: Universal Serial Bus (USB), Peripheral Component Interconnect Express (PCI-Express), Serial Advanced Technology Attachment (SATA), and M-Phy for Universal Flash Storage (UFS). In example embodiments, the data storage system 2000 may operate with power supplied by an external host through the connector 2006. The data storage system 2000 may further include a Power Management Integrated Circuit (PMIC) distributing power supplied by the external host to the controller 2002 and the semiconductor package 2003.

The controller 2002 may write data to the semiconductor package 2003 or read data from the semiconductor package 2003. The operation speed of the data storage system 2000 may be improved. The DRAM 2004 may be a buffer memory to alleviate the speed difference between the semiconductor package 2003, which is a data storage space, and an external host. The DRAM 2004 included in the data storage system 2000 may also operate as a type of cache memory. A space for temporarily storing data may be provided during control operations for the semiconductor package 2003. When the data storage system 2000 includes DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b that are spaced apart from each other. The first and second semiconductor packages 2003a and 2003b may each include a plurality of semiconductor chips 2200. Each of the first and second semiconductor packages 2003a and 2003b may include a package substrate 2100, semiconductor chips 2200 on a package substrate 2100, adhesive layers 2300 disposed on the lower surface of each semiconductor chip 2200, a connection structure 2400 that electrically connects the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 11. Each of the semiconductor chips 2200 may include gate stack structures 3210 and channel structures 3220. Each of the semiconductor chips 2200 may include the semiconductor device described above with reference to FIGS. 1 to 9.

In example embodiments, the connection structure 2400 may be a bonding wire that electrically connects the input/output pad 2210 and the top pads 2130 of the package substrate 2100. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. According to example embodiments, in each of the first and second semiconductor packages 2003a and 2003b, instead of the bonding wire-type connection structure 2400, the semiconductor chips 2200 may be electrically connected to each other by a connection structure including a through electrode (Through Silicon Via, TSV).

In example embodiments, the controller 2002 and the semiconductor chips 2200 may be included in one package. In an example embodiment, the controller 2002 and the semiconductor chips 2200 are mounted on a separate interposer board different from the main board 2001, and the controller 2002 and the semiconductor chips 2200 may be connected to each other through interconnection formed on the interposer substrate.

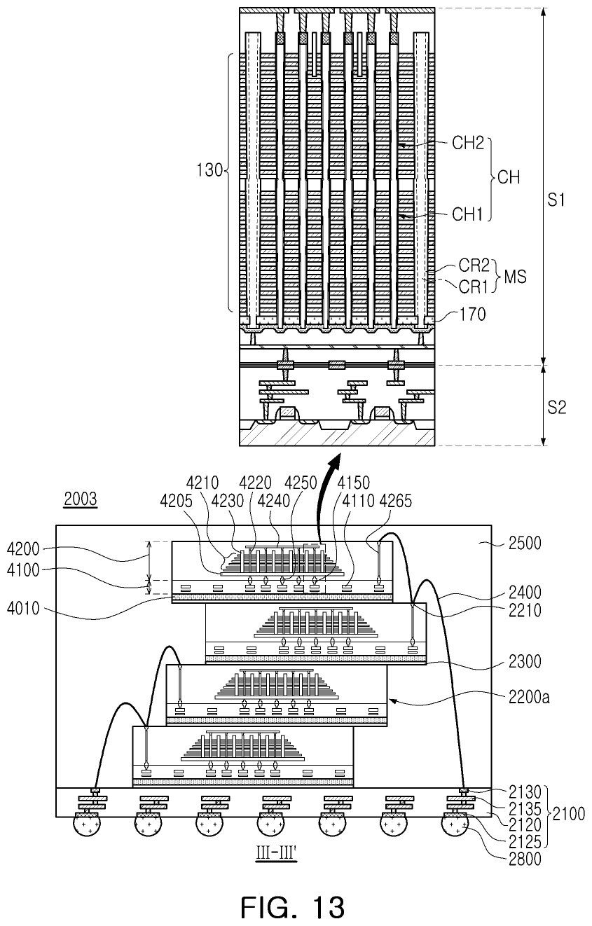

FIG. 13 is a cross-sectional view schematically illustrating a semiconductor package according to an example embodiment. FIG. 13 illustrates an example embodiment of the semiconductor package 2003 of FIG. 12, and conceptually illustrates the area where the semiconductor package 2003 in FIG. 12 is cut along the cutting line III-III′.

Referring to FIG. 13, in the semiconductor package 2003, the package substrate 2100 may be a printed circuit board. The package substrate 2100 may include a package substrate body portion 2120, package upper pads 2130 disposed on the upper surface of the package substrate body 2120, lower pads 2125 disposed on or exposed through the lower surface of the package substrate body 2120, and internal interconnections 2135 electrically connecting the upper pads 2130 and the lower pads 2125 inside the package substrate body 2120. The upper pads 2130 may be electrically connected to the connection structures 2400. The lower pads 2125 may be connected to the interconnection structures 2005 of the main board 2001 of the electronic system 2000 as illustrated in FIG. 12 through conductive connectors 2800.

Each of the semiconductor chips 2200a may include a semiconductor substrate 4010, a first structure 4100 on the semiconductor substrate 4010, and a second structure 4200 bonded to the first structure 4100 on the semiconductor substrate 4010 using a wafer bonding method. The first structure 4100, unlike in FIG. 2A, is illustrated packaged to be located at the bottom, but is not limited thereto.

The first structure 4100 may include a peripheral circuit area including peripheral interconnection 4110 and first bonding structures 4150. The second structure 4200 may include a common source line 4205, a gate stack structure 4210, channel structures 4220 and separation regions 4230 penetrating the gate stack structure 4210, and second bonding structures 4250 electrically connected to the memory channel structures 4220 and the word lines WL of the gate stack structure 4210 (see FIG. 11), respectively. For example, the second bonding structures 4250 may be respectively electrically connected to the memory channel structures 4220 and word lines WL through separate gate contacts electrically connected to the bit lines 4240 and word lines WL, which are electrically connected to the memory channel structures 4220. The first bonding structures 4150 of the first structure 4100 and the second bonding structures 4250 of the second structure 4200 may be joined while contacting each other. The joined portions of the first bonding structures 4150 and the second bonding structures 4250 may be formed of, for example, copper (Cu).

As illustrated in the enlarged view, the second structure 4200 may include a supporter layer 170 penetrated by the channel structures CH and the first regions CR1 of the separation regions MS, and the supporter layer 170 may be connected between adjacent memory blocks. Each of the semiconductor chips 2200a may further include an input/output pad 2210 and an input/output connection wire 4265 below the input/output pad 2210. The input/output connection wire 4265 may be electrically connected to some of the second bonding structures 4210.

The semiconductor chips 2200a may be electrically connected to each other by connection structures 2400 in the form of bonding wires. However, in example embodiments, semiconductor chips within one semiconductor package, such as the semiconductor chips 2200a, may be electrically connected to each other by a connection structure including a through electrode (TSV).

As set forth above, according to example embodiments, in a structure in which two or more substrate structures are bonded, a semiconductor device having improved reliability and integration and a data storage system including the same may be provided by including a supporter layer penetrated by channel structures.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a first substrate structure; and
a second substrate structure connected to the first substrate structure and including a substrate, circuit elements on a lower surface of the substrate that faces the first substrate structure, and second bonding metal layers between the lower surface of the substrate and the first substrate structure,
wherein the first substrate structure comprises:
gate electrodes stacked and spaced apart from each other along a first direction that is perpendicular to the lower surface of the substrate;
a supporter layer on the gate electrodes;
channel structures extending in the first direction and penetrating the gate electrodes, the channel structures respectively including a channel layer and a channel pad on a lower end;
separation regions extending in the first direction and in a second direction that is perpendicular to the first direction, the separation regions penetrating the gate electrodes and being spaced apart from each other along a third direction that is perpendicular to the first and second directions; and
first bonding metal layers connected to the second bonding metal layers,
wherein the separation regions respectively include first regions spaced apart from each other along the second direction and a second region on side surfaces of the first regions and extending in the second direction,
wherein the first regions and the channel structures penetrate the supporter layer, and
wherein a portion of a lower surface of the supporter layer is in contact with the second region.

2. The semiconductor device of claim 1, wherein inner side surfaces of the supporter layer are directly on the side surfaces of the first regions.

3. The semiconductor device of claim 1, wherein the supporter layer includes a region overlapping with the second region in the first direction.

4. The semiconductor device of claim 1, wherein the second region does not penetrate the supporter layer.

5. The semiconductor device of claim 1, wherein upper ends of the channel structures and upper ends of the separation regions are coplanar with or extend beyond an upper surface of the supporter layer.

6. The semiconductor device of claim 1, wherein uppermost surfaces of the separation regions are coplanar with an upper surface of the supporter layer.

7. The semiconductor device of claim 1, wherein the channel structures respectively include a first end adjacent to the supporter layer and a second end opposite to the first end and having the channel pad thereon.

8. The semiconductor device of claim 1, wherein the supporter layer comprises at least one of Si, SiGe, SiC, AlₓO_{y}, or a metal material.

9. The semiconductor device of claim 1, wherein the first substrate structure further comprises interlayer insulating layers alternately stacked with the gate electrodes, and the supporter layer comprises a material different from a material of the interlayer insulating layers.

10. The semiconductor device of claim 1, wherein the first substrate structure further comprises a source conductive layer on the supporter layer and in contact with the channel layer.

11. The semiconductor device of claim 10, wherein the source conductive layer overlaps the second region in the first direction.

12. The semiconductor device of claim 1, wherein the separation regions have curved side surfaces facing the side surfaces of the first regions in plan view.

13. The semiconductor device of claim 1, wherein the first substrate structure further comprises string channel structures penetrating a lowest gate electrode among the gate electrodes and respectively connected to the channel structures.

14. A semiconductor device comprising:
a first substrate structure; and
a second substrate structure connected to the first substrate structure and including a substrate, circuit elements on one surface of the substrate, and second bonding metal layers on the circuit elements,
wherein the first substrate structure comprises:
gate electrodes stacked and spaced apart from each other along a first direction that is perpendicular to the one surface of the substrate;
a supporter layer on the gate electrodes;
channel structures penetrating the gate electrodes, extending in the first direction, and respectively including a channel layer;
separation regions extending in the first direction and in a second direction that is perpendicular to the first direction, the separation regions penetrating the gate electrodes, and being spaced apart from each other along a third direction that is perpendicular to the first and second directions; and
first bonding metal layers connected to the second bonding metal layers,
wherein the channel structures respectively penetrate at least a portion of the supporter layer along the first direction, and
wherein the supporter layer includes regions overlapping the separation regions along the first direction.

15. The semiconductor device of claim 14, wherein a first portion of each of the separation regions extends completely through the supporter layer in the first direction.

16. The semiconductor device of claim 15, wherein a second portion of each of the separation regions is in contact with one surface of the supporter layer.

17. The semiconductor device of claim 14, wherein the separation regions respectively include first regions spaced apart from each other along the second direction, and a second region on side surfaces of the first regions and extending in the second direction, and the first regions extend completely through the supporter layer.

18. The semiconductor device of claim 14, wherein the first substrate structure further comprises interlayer insulating layers alternately stacked with the gate electrodes, and the supporter layer comprises a conductive material or an insulating material that is different from a material of the interlayer insulating layers.

19. A data storage system comprising:
a semiconductor storage device comprising a first substrate structure including channel structures and first bonding metal layers, a second substrate structure including circuit elements and second bonding metal layers connected to the first bonding metal layers along a bonding surface, and an input/output pad electrically connected to the circuit elements; and
a controller configured to be electrically connected to the semiconductor storage device through the input/output pad, and configured to control the semiconductor storage device,
wherein the first substrate structure further comprises:
gate electrodes stacked and spaced apart from each other along a first direction that is perpendicular to the bonding surface;
a supporter layer on the gate electrodes;
channel structures penetrating the gate electrodes, extending in the first direction, and respectively including a channel layer, a channel dielectric layer, and a channel pad at end portions thereof; and
separation regions extending in the first direction and a second direction that is perpendicular to the first direction, the separation regions penetrating the gate electrodes,
wherein the channel structures penetrate the supporter layer, and
wherein the supporter layer is spaced apart from the channel layer by the channel dielectric layer.

20. The data storage system of claim 19, wherein the supporter layer includes a region crossing the separation regions along a third direction, which is perpendicular to the first and second directions, on each of the separation regions.
